(19) United States
(12) Patent Application Publication
(10) Pub. No.: US 2012/0007071 A1
(43) Pub. Date: Jan. 12, 2012

(54) ORGANIC LIGHT-EMITTING DEVICE, AND METHOD FOR MANUFACTURING SAME

(76) Inventors: Mun-Kyu Joo, Busan (KR); Jeoung-Kwen Noh, Daejeon (KR); Jong-Seonk Kim, Seoul (KR)

(21) Appl. No.: 13/257,222

(22) PCT Filed: Mar. 17, 2010
(86) PCT No.: PCT/KR10/01652

§ 371 Date: Sep. 16, 2011

(30) Foreign Application Priority Data
Mar. 17, 2009 (KR) 10-2009-0022810

(51) Int. Cl. H01L 51/54; H01L 51/56

(52) U.S. Cl. 257/40; 438/46; 257/E51.049; 257/E51.018

(57) ABSTRACT

An exemplary embodiment of the present invention provides an organic light-emitting device, comprising: a first electrode; a second electrode; and a light emitting layer that is disposed between the first electrode and the second electrode, wherein the organic light-emitting device further comprises a first organic material layer that is contacted with the first electrode and a second organic material layer that is contacted with the second electrode, the first and the second organic material layers comprise a compound represented by Formula 1, and a third organic material layer comprising an n-type dopant between the second organic material layer contacted with the second electrode and the light emitting layer is included, and a method for manufacturing the same.

### TECHNICAL FIELD

The present invention relates to an organic light-emitting device and a method for manufacturing the same, and more particularly, to an organic light-emitting device that can use a material having various work functions as a material of an anode and a cathode and can prevent an organic material layer from being damaged when an upper electrode is formed and a method for manufacturing the same.

This application claims priority from Korean Patent Application No. 10-2009-0022810 filed on Mar. 17, 2009 in the KIPO, the disclosure of which is incorporated herein by reference in its entirety.

### BACKGROUND ART

An organic light-emitting device (OLED) is generally composed of two electrodes (an anode and a cathode) and one or more organic material layers that are disposed between the electrodes. In the organic light-emitting device having this structure, if a voltage is applied between the two electrodes, a hole from an anode and an electron from a cathode flow into an organic material layer, they are recombined with each other to form an exciton, and a photon corresponding to an energy difference is emitted while the exciton falls back to the ground state. By this principle, the organic light-emitting device emits visible rays, and an information display device or illumination device may be manufactured by using this.

However, in a manufacturing process of the organic light-emitting device, in the case where an electrode disposed on an organic material layer is formed of a conductive oxide film having transparency such as IZO or ITO, if a resistive heating evaporation method is used, an intrinsic chemical composition ratio of oxide is broken by thermal decomposition during the evaporation process by heat, such that properties such as electroconductivity and visible ray transmittance are lost. Accordingly, when the conductive oxide film is deposited, the resistive heating evaporation method cannot be used, and, mostly, methods such as sputtering using a plasma are used.

However, in the case where the electrode is formed by the method such as sputtering on the organic material layer, the organic material layer may be damaged by electric charge particles existing in a plasma used in the sputtering process.

Therefore, in order to manufacture the good organic light-emitting device, a damage of the organic material layer occurring when the electrode is formed by the method such as sputtering on the organic material layer should be removed or minimized.

### DISCLOSURE

### Technical Problem

The present invention has been made in an effort to provide an organic light-emitting device that can emit light at both sides by forming an anode and a cathode using a material with a high work function because the material having various work functions can be used as the material of the anode and the cathode and an organic material layer can be prevented from being damaged when an upper electrode is formed, and a method for manufacturing the same.

### Technical Solution

An exemplary embodiment of the present invention provides an organic light-emitting device comprising: a first electrode; a second electrode; and a light emitting layer that is disposed between the first electrode and the second electrode, wherein the organic light-emitting device further comprises a first organic material layer that is contacted with the first electrode and a second organic material layer that is contacted with the second electrode, the first and second organic material layers comprise a compound represented by the following Formula 1, and a third organic material layer comprising an n-type dopant between the second organic material layer contacted with the second electrode and the light emitting layer is included:

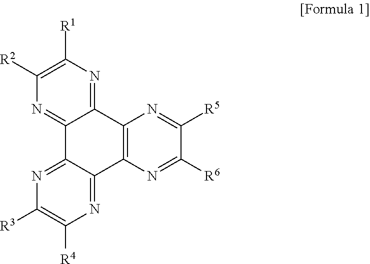

wherein R¹ to R⁶ are each selected from the group consisting of hydrogen, a halogen atom, nitrile (—CN), nitro (—NO₂), sulfonyl (—SO₂R), sulfoxide (—SOR), sulfonamide (—SO₂NR), sulfonate (—SO₃R), trifluoromethyl (—CF₃), ester (—COOR), amide (—CONHR or —CONRR′), substituted or unsubstituted straight-chained or branched-chained C₁-C₁₂ alkoxy, substituted or unsubstituted straight-chained or branched-chained C₁-C₁₂ alkyl, substituted or unsubstituted aromatic or non-aromatic hetero cycle, substituted or unsubstituted aryl, substituted or unsubstituted mono- or di-arylamine, and substituted or unsubstituted aralkylamine, and R and R′ are each selected from the group consisting of substituted or unsubstituted C₁-C₆₀ alkyl, substituted or unsubstituted aryl and substituted or unsubstituted 5 to 7-membered hetero cycle.

Another exemplary embodiment of the present invention provides a method for manufacturing an organic light-emitting device, comprising: a step of forming a first electrode; a step of forming a first organic material layer contacted with the first electrode and comprising a compound of the Formula 1; a step of forming a light emitting layer on the first organic material layer comprising the compound of the Formula 1; a step of forming a third organic material layer comprising an n-type dopant on the light emitting layer; a step of forming a second organic material layer comprising a compound of the Formula 1 on the third organic material layer comprising the n-type dopant; and a step of forming a second electrode so that the second electrode is contacted with the second organic material layer comprising a compound of the Formula 1.

### Advantageous Effects

According to exemplary embodiments of the present invention, a material having various work functions may be used as a material of an anode and a cathode of an organic light-emitting device, and it is possible to prevent an organic material layer from being damaged when an upper electrode is formed. Therefore, it is possible to provide an organic light-emitting device that can emit light at both sides by forming the anode and the cathode made of the material having the high work function.

### BRIEF DESCRIPTION OF DRAWINGS

FIG. 1 illustrates an energy relationship between layers constituting an organic light-emitting device according to an exemplary embodiment of the present invention.

FIG. 2 illustrates a laminate structure of the organic light-emitting device according to the exemplary embodiment of the present invention.

FIG. 3 is a graph illustrating comparison of voltage-current density properties of Example 1 (device 2) and Comparative Example 2 (device 1) according to the exemplary embodiment of the present invention.

FIG. 4 is a graph illustrating comparison of current density-efficiency properties in a first electrode direction among properties of Example 1 (device 2) and Comparative Example 2 (device 1) according to the exemplary embodiment of the present invention.

FIG. 5 is a graph illustrating comparison of current density-efficiency properties in a second electrode direction among properties of Example 1 (device 2) and Comparative Example 2 (device 1) according to the exemplary embodiment of the present invention.

FIG. 6 is a graph illustrating a summated value of current density-efficiency in the first and second electrode directions among properties of Example 1 (device 2) and Comparative Example 2 (device 1) according to the exemplary embodiment of the present invention.

FIG. 7 is a graph illustrating voltage-current density properties of Comparative Example 1 (device 4) according to the exemplary embodiment of the present invention.

FIG. 8 is a graph illustrating comparison of voltage-current density properties of Example 1 (device 2) and Example 2 (device 3) according to the exemplary embodiment of the present invention.

FIG. 9 is a graph illustrating comparison of current density-efficiency properties in a first electrode direction among properties of Example 1 (device 2) and Example 2 (device 3) according to the exemplary embodiment of the present invention.

FIG. 10 is a graph illustrating comparison of current density-efficiency properties in a second electrode direction among properties of Example 1 (device 2) and Example 2 (device 3) according to the exemplary embodiment of the present invention.

FIG. 11 is a graph illustrating comparison of current density-efficiency properties in the first and second electrode directions among properties of Example 1 (device 2) and Example 2 (device 3) according to the exemplary embodiment of the present invention.

### BEST MODE

An organic light-emitting device according to an exemplary embodiment of the present invention comprises a first electrode; a second electrode; and a light emitting layer that is disposed between the first electrode and the second electrode, wherein the organic light-emitting device further comprises a first organic material layer that is contacted with the first electrode and a second organic material layer that is contacted with the second electrode, the first and second organic material layers comprise a compound represented by Formula 1, and a third organic material layer comprising an n-type dopant between the second organic material layer contacted with the second electrode and the light emitting layer is included.

Herein, the first and second organic material layers comprise a compound represented by Formula 1, and the organic material layers may be formed of the same material. By using the organic material layer comprising the compound of Formula 1 as the first organic material layer contacted with the first electrode and the second organic material layer contacted with the second electrode, a driving voltage may be more reduced and a current efficiency may be more increased as compared to a known art. In addition, in the case where the first organic material layer contacted with the first electrode and the second organic material layer contacted with the second electrode are formed of the same material, organic material layers formed of various functional materials may be applied to an interface between the first electrode and the first organic material layer contacted with the first electrode and/or an interface between the second organic material layer contacted with the second electrode and the third organic material layer comprising the n-type dopant, and as described above, in the case where the functional material layer is further included, effects such as a decrease of the voltage, an increase of the efficiency, and a decrease of electrode resistance can be expected. In the case where the functional material layer is disposed at an interface between the first electrode and the first organic material layer contacted with the first electrode, it is preferable that the layer is a thin film of metal or an alloy thereof or a metal oxide layer). In the case where the functional material layer is disposed at an interface of the second organic material layer contacted with the second electrode and the third organic material layer comprising the n-type dopant, it is preferable that the layer is a metal oxide layer or a metal salt layer.

Exemplary compounds of Formula 1 comprise compounds of the following Formulas 1-1 to 1-6.

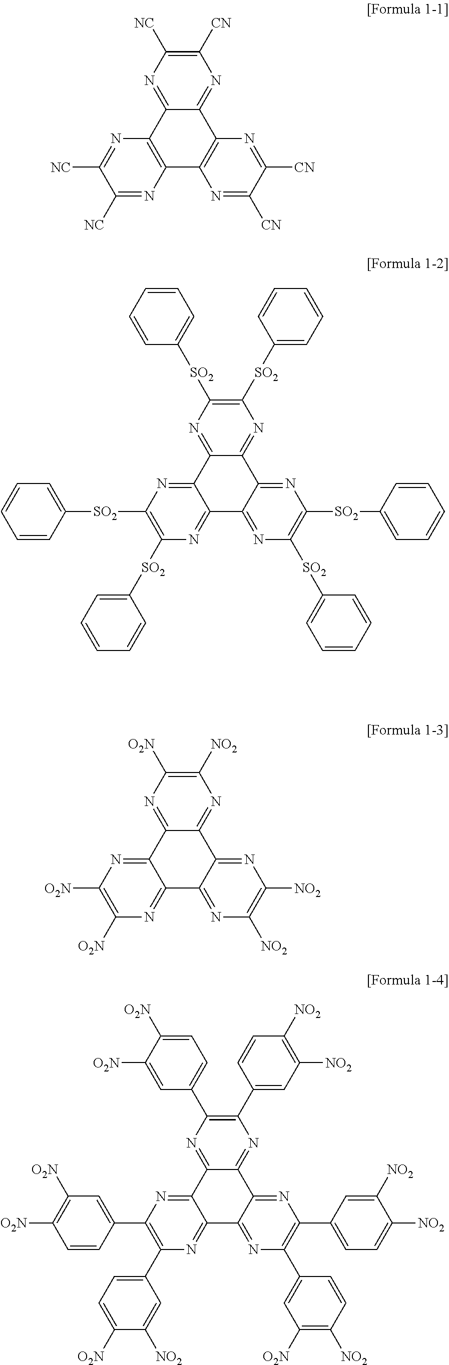

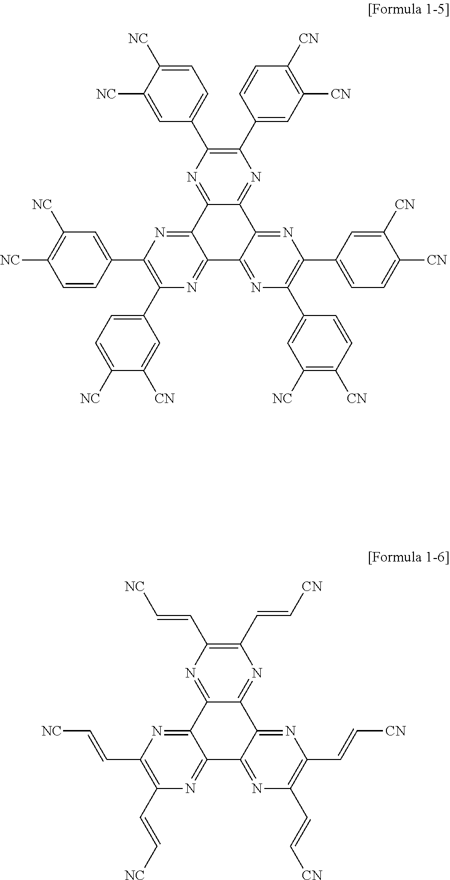

In the exemplary embodiment of the present invention, the first electrode and the second electrode may be formed of the material having various work functions by the first and second organic material layers contacted with the first electrode and the second electrode, respectively. For example, the first electrode and the second electrode may be formed of a material having a Fermi energy level of 2 eV to 6 eV, in particular, 2 eV to 4 eV. As the electrode material, a material selected from the group consisting of metal, metal oxide and a conductive polymer may be included. In detail, as the electrode material, there are carbon, cesium, potassium, lithium, calcium, sodium, magnesium, nirconium, indium, aluminum, silver, tantalum, vanadium, chromium, copper, zinc, iron, tungsten, molybdenum, nickel, gold, other metals and alloys thereof; zinc oxide, indium oxide, tin oxide, indium tin oxide (ITO), indium zinc oxide, and other similar metal oxides; oxides such as ZnO:Al and SnO₂:Sb and a mixture of metals. In the organic light-emitting device according to the exemplary embodiment of the present invention, in the case where the first electrode is formed of a transparent material, the organic light-emitting device may be a bottom emission type, in the case where the second electrode is formed of the transparent material, the organic light-emitting device may be a top emission type, and in the case where the first and the second electrodes are formed of the transparent material, the organic light-emitting device may be a double-sided emission type.

As described above, the first electrode and the second electrode may be formed of the material having the high work function, and in this case, the double-sided emission device may be manufactured by using the transparent material having the high work function. For example, the first electrode and the second electrode may be formed of one or more transparent metal oxides (transparent conducting oxide) selected from indium zinc oxide (IZO) and zinc oxide (ZnO), respectively.

The first electrode may further comprise the thin film of the metal or the alloy thereof, or the metal oxide layer thereof at the interface with the first organic material layer contacted with the first electrode.

As described above, in the case where the thin film of the metal or the alloy thereof, or the metal oxide layer is further included, since a career mobility of a charge and electroconductivity may be increased, effects for reducing a threshold voltage and a driving voltage of the device may be provided. In addition, in the case where the organic light-emitting device is manufactured by enlarging an area thereof, if a transparent electrode formed of metal oxide such as indium zinc oxide is used as the first electrode, electrode resistance may be reduced, thereby more uniformly obtaining light of a light emitting portion of the device.

As the material of the layer further included in the first electrode, in detail, there are aluminum (Al), silver (Ag), zinc (Zn), niobium (Nb), zirconium (Zr), tin (Sn), tantalum (Ta), vanadium (V), mercury (Hg), gallium (Ga), Indium (In), cadmium (Cd), boron (B), hafnium (Hf), lanthanum (La), titanium (Ti), calcium (Ca), magnesium (Mg) and an alloy of metal selected therefrom and neodymium (Nd) or palladium (Pd), and metal oxides such as Li₂O, Na₂O, Rb₂O, Cs₂O, MgO, and CaO are included, but the material is not limited thereto.

In the case where the thin film of metal or the alloy thereof, or the metal oxide layer thereof is further included, the thickness thereof may be controlled in consideration of transmittance and electroconductivity of the wavelength of the visible ray region, and it is preferable that the thickness thereof is 1 to 300 Å.

In the exemplary embodiment of the present invention, it is preferable that the first organic material layer contacted with the first electrode is contacted with the p-type organic material layer. In this case, since the compound of Formula 1 is an n-type organic material, an NP conjugation structure between the first organic material layer contacted with the first electrode and the p-type organic material layer may be formed. It is preferable that an energy level difference is controlled so that the energy level difference is reduced between the LUMO level of the first organic material layer contacted with the first electrode and the HOMO level of the p-type organic material layer. The energy difference between the LUMO energy level of the first organic material layer contacted with the first electrode and the HOMO energy level of the p-type organic material layer is preferably 1 eV or less, and more preferably about 0.5 eV or less. This energy difference is preferably −1 eV to 1 eV or less in view of selection of the material, and more preferably about 0.01 to 1 eV.

In the case where the energy level is selected within the above numerical range, a hole is easily injected through the LUMO energy level of the organic material layer contacted with the first electrode to the HOMO energy level of the p-type organic material layer. If the energy difference between the HOMO energy level of the p-type organic material layer and the LUMO energy level of the organic material layer contacted with the first electrode is larger than 1 eV, since the NP conjugation does not easily occur between the p-type organic material layer and the first organic material layer contacted with the first electrode, a driving voltage for hole injection is increased. That is, in the exemplary embodiment of the present invention, the NP conjugation should satisfy a physical contact between the n-type organic material layer and the p-type organic material layer and the above all energy relationships.

If the NP conjugation is formed, the hole or the electron is easily formed by an external voltage or a light source. That is, the hole is easily formed in the p-type organic material layer and the electron is easily formed in the first organic material layer contacted with the first electrode by the NP conjugation. Since the hole and the electron are simultaneously generated in the NP conjugation, the electron is transported through the first organic material layer contacted with the first electrode in a first electrode direction, and the hole is transported in a p-type organic material layer direction. Accordingly, the hole or the electron is easily generated within the energy difference range, such that since the concentration of the charge is increased, the increase of the driving voltage of the device may be decreased. The p-type organic material layer may be a hole transport layer or a p-type light emitting layer.

In the case where the p-type organic material layer is the hole transport layer, the layer may be disposed between the first organic material layer contacted with the first electrode and the light emitting layer. Herein, it is preferable that the HOMO (highest occupied molecular orbital) energy level of the hole transport layer is 5 eV or more, and more preferably the level is 5 eV to 6 eV. In the case where the level is 5 eV or more, the effective charge generation in the hole injection layer may be provided.

The light emitting layer may be formed of a material that receives the holes and the electrons from the hole transport layer and the electron transport layer and combines them, such that light at a range of visible rays is emitted, and it is preferable to use the material having excellent photon efficiency to fluorescence or phosphorescence. As detailed examples thereof, there are a 8-hydroxy-quinoline aluminum complex (Alq₃); a carbazole-based compound; a dimerized styryl compound; BAlq; a 10-hydroxybenzoquinoline-metal compound; a benzoxazole, benzthiazole, and benzimidazole-based compound; a poly(p-phenylenevinylene) (PPV)-based polymer; a spiro compound; polyfluorene, lubrene, and the like, but it is not limited thereto.

The organic light-emitting device according to the exemplary embodiment of the present invention comprises the organic material layer comprising the compound of Formula 1 as the second organic material layer contacted with the second electrode, and the third organic material layer comprising the n-type dopant disposed between the second organic material layer contacted with the second electrode and the light emitting layer.

The second organic material layer contacted with the second electrode comprising the compound of Formula 1 acts as a connecter between the third organic material layer comprising the n-type dopant and the second electrode, and may be formed so that the second electrode is formed of the material having various work functions. Accordingly, the second electrode may be formed of the material having the high work function, for example, the transparent metal oxide such as ITO, and IZO by the second organic material layer contacted with the second electrode. In addition, in the case where the second electrode is formed by using the technology for forming a thin film damaging the organic material layer by providing particles having the charge or the high kinetic energy, such as sputtering, physical vapor deposition (PVD) using a laser, and ion beam assisted deposition, the second organic material layer contacted with the second electrode may act as a buffer layer, thus preventing the damage of the organic material layer. In particular, in the case where the second electrode is formed of the transparent electrode, the sputtering process is mainly used, and in this case, a general organic material is damaged during the process, but since the compound of Formula 1 has the high crystallinity, the transparent second electrode may be effectively configured without the damage of the organic material layer.

It is preferable that the thickness of the third organic material layer comprising the n-type dopant is 1 to 50 Å. In the case where the thickness of the third organic material layer comprising the n-type dopant is more than 50 Å, the light emission efficiency may be reduced by absorbing visible rays, and in the case where the thickness is less than 1 Å, since the uniformity of the thin film may be reduced, it may be difficult to effectively inject the electron.

In the third organic material layer comprising the n-type dopant, the n-type dopant may be an organic material or an inorganic material. In the case where the n-type dopant is the inorganic material, the metal compound including alkali metal, for example, Li, Na, K, Rb, Cs or Fr; alkali earth metal, for example, Be, Mg, Ca, Sr, Ba or Ra; rare earth metal, for example, La, Ce, Pr, Nd, Sm, Eu, Tb, Th, Dy, Ho, Er, Em, Gd, Yb, Lu, Y or Mn; or one or more of the above metals may be included. In addition, the n-type dopant may be a material including cyclopentadiene, cycloheptatriene, 6-membered heterocycle or compensated cycle including the above cycles.

Herein, the weight of the n-type dopant may be 1 to 50 wt % on the basis of the total weight of the organic material layer material comprising the n-type dopant. In the case where the n-type dopant is used in the above wt % range, there are advantages in that it is easy to effectively inject the electron and it is possible to minimize absorption of light. In the exemplary embodiment of the present invention, the method for doping the n-type dopant may use a method widely known in the art, and the scope of the present invention is not limited to the specific method.

In the third organic material layer comprising the n-type dopant, as the doped material, that is, the host material, the electron injection or transport material may be used. For example, as the host material, a compound having a functional group selected from an imidazole group, an oxazole group and a thiazole group may be used, but the material is not limited thereto.

Detailed examples of the compound that comprises one or more functional groups selected from the imidazole group, the oxazole group, and the thiazol group are the compounds of the following Formula 2 or Formula 3:

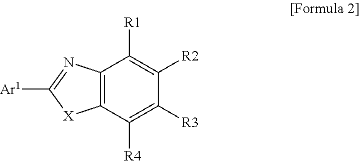

In Formula 2, R¹ to R⁴ may be the same as or different from each other, are each independently a hydrogen atom; a C₁˜C₂₀ alkyl group substituted or unsubstituted by one or more groups selected from the group consisting of a halogen atom, an amino group, a nitrile group, a nitro group, a C₁˜C₂₀ alkyl group, a C₂˜C₂₀ alkenyl group, a C₁˜C₂₀ alkoxy group, a C₂˜C₃₀ cycloalkyl group, a C₃˜C₃₀ heterocycloalkyl group, a C₅˜C₂₀ aryl group, and a C₂˜C₂₀ heteroaryl group; a C₃˜C₃₀ cycloalkyl group substituted or unsubstituted by one or more groups selected from the group consisting of a halogen atom, an amino group, a nitrile group, a nitro group, a C₁˜C₂₀ alkyl group, a C₂˜C₂₀ alkenyl group, a C₁˜C₃₀ alkoxy group, a C₃˜C₃₀ cycloalkyl group, a C₃˜C₃₀ heterocycloalkyl group, a C₅˜C₂₀ aryl group, and a C₂˜C₃₀ heteroaryl group; a C₅˜C₂₀ aryl group substituted or unsubstituted by one or more groups selected from the group consisting of a halogen atom, an amino group, a nitrile group, a nitro group, a C₁˜C₂₀ alkyl group, a C₂˜C₂₀ alkenyl group, a C₁˜C₃₀ alkoxy group, a C₃˜C₃₀ cycloalkyl group, a C₃˜C₃₀ heterocycloalkyl group, a C₅˜C₃₀ aryl group, and a C₂˜C₃₀ heteroaryl group; or a C₂˜C₃₀ heteroaryl group substituted or unsubstituted by one or more groups selected from the group consisting of a halogen atom, an amino group, a nitrile group, a nitro group, a C₁˜C₃₀ alkyl group, a C₂˜C₃₀ alkenyl group, a C₁˜C₃₀ alkoxy group, a C₃˜C₃₀ cycloalkyl group, a C₃˜C₃₀ heterocycloalkyl group, a C₅˜C₃₀ aryl group, and a C₂˜C₃₀ heteroaryl group, and may form aliphatic, aromatic, aliphatichetero or aromatichetero fused cycle or a Spiro bond in conjunction with the adjacent group; Ar¹ is a hydrogen atom, a substituted or unsubstituted aromatic cycle or a substituted or unsubstituted aromatic hetero cycle; X is O, S or NR^{a}; and R^{a} is hydrogen, C₁-C₇ aliphatic hydrocarbon, aromatic cycle or aromatic hetero cycle, and

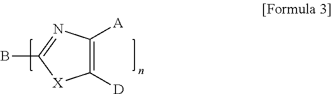

in Formula 3, X is O, S, NR^{b} or C₁-C₇ divalent hydrocarbon group; A, D and R^{b} are each a hydrogen atom, a nitrile group (—CN), a nitro group (—NO₂), C₁-C₂₄ alkyl, C₅˜C₂₀ aromatic cycle or substituted aromatic cycle including the hetero atom, halogen, alkylene that can form a blending cycle in conjunction with the adjacent cycle, or alkylene including the hetero atom; A and D may be connected to each other to form aromatic or hetero aromatic cycle; B is substituted or unsubstituted alkylene or arylene connecting a plurality of hetero cycles as connection units to be conjugated or non-conjugated in the case where n is 2 or more, and a substituted or unsubstituted alkyl or aryl in the case where n is 1; and n is an integer of 1 to 8.

An example of the compound of Formula 2 includes a compound known in Korean Unexamined Patent Application Publication No. 2003-0067773, and an example of the compound of Formula 3 includes a compound disclosed in U.S. Pat. No. 5,645,948 and a compound disclosed in WO05/097756. The contents of the documents are incorporated in the present specification.

In detail, the compound of the following Formula 4 is included in the compound of Formula 2:

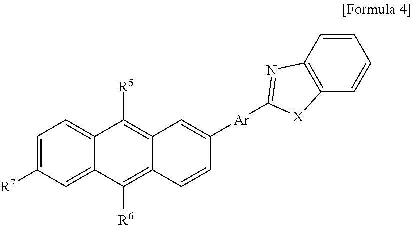

In Formula 4, R⁵ to R⁷ are the same as or different from each other, and each independently a hydrogen atom, C₁-C₂₀ aliphatic hydrocarbon, an aromatic cycle, an aromatic hetero cycle or an aliphatic or aromatic compensated cycle; Ar is a direct bond, an aromatic cycle or an aromatic hetero cycle; X is O, S or NR^{a}; R^{a} is a hydrogen atom, C₁-C₇ aliphatic hydrocarbon, an aromatic cycle or an aromatic hetero cycle; and the case where R⁵ and R⁶ are simultaneously hydrogen is excluded.

In addition, the compound of the following Formula 5 is included in the compound of Formula 3:

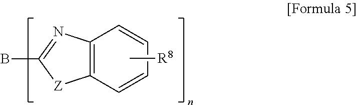

In Formula 5, Z is O, S or NR^{b}; R⁸ and R^{b} are a hydrogen atom, C₁-C₂₄ alkyl, substituted aromatic cycle including C₅-C₂₀ aromatic cycle or a hetero atom, halogen, or alkylene forming a fused cycle in conjunction with a benzazole cycle or alkylene including the hetero atom; B is alkylene, arylene, substituted alkylene, or substituted arylene connecting a plurality of hetero cycles as connection units to be conjugated or non-conjugated in the case where n is 2 or more, and substituted or unsubstituted alkyl or aryl in the case where n is 1; and n is an integer of 1 to 8).

As the preferable compound having the imidazole group, there are compounds having the following structures:

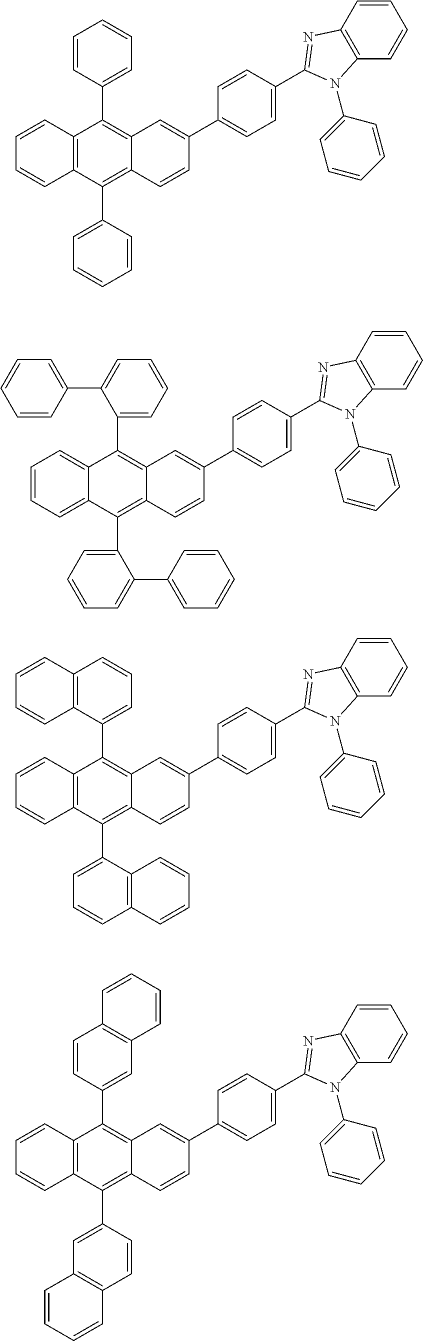

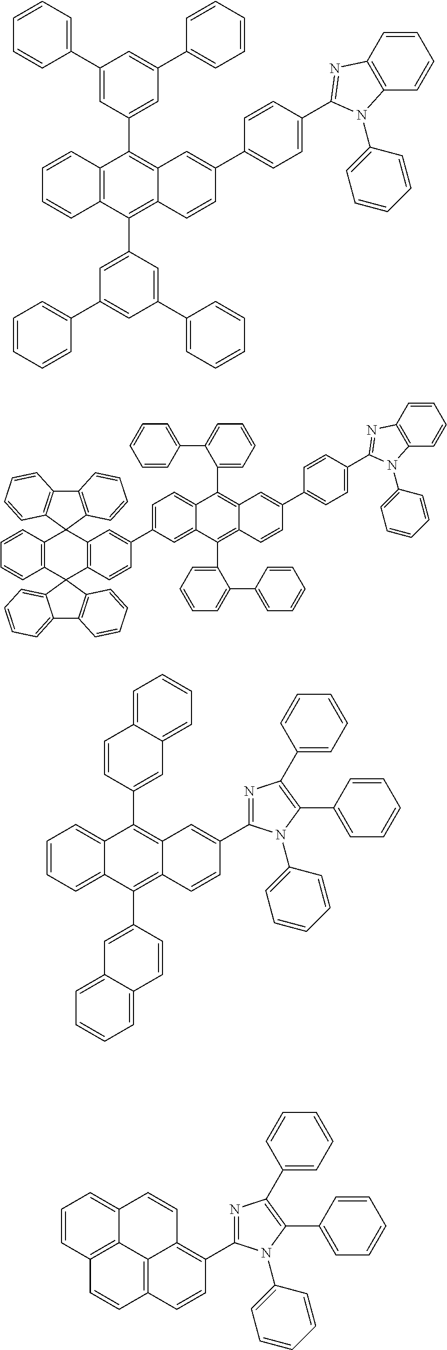

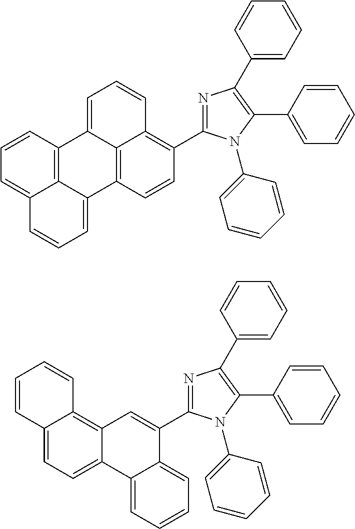

The organic material layer comprising the n-type dopant reduces an energy barrier with the organic material layer contacted with the second electrode by n-type doping, such that an electron injection characteristic may be improved. The difference between the LUMO (Lowest unoccupied molecular orbital) level of the third organic material layer comprising the n-type dopant and the LUMO level of the second organic material layer contacted with the second electrode is preferably 4 eV or less, and more preferably 2 eV to 3 eV. In the case where the organic material layer of more than 4 eV is used, the energy barrier with the organic material layer contacted with the second electrode is increased, thus reducing the electron injection characteristic. In the case where the effective electron injection is not easy, the driving voltage of the device may be increased.

The metal oxide layer or the metal salt layer may be further included between the third organic material layer comprising the n-type dopant and the second organic material layer contacted with the second electrode.

The metal oxide layer or the metal salt layer may effectively block the hole transported from the HOMO energy level of the third organic material layer comprising the n-type dopant to the second organic material layer contacted with the second electrode in the course of electron injection from the second organic material layer contacted with the second electrode layer to the third organic material layer comprising the n-type dopant. Thereby, a removing phenomenon between the electron and the hole is minimized, and the injection of the electron to the third organic material layer comprising the n-type dopant is made easy, such that efficiency of the device is increased.

As examples of the detailed metal oxide, there are Li₂O, Na₂O, Rb₂O, Cs₂O, MgO, and CaO, and examples of the metal salt may include LiF, NaF, KF, RbF, CsF, MgF₂, CaF₂, SrF₂, BaF₂, LiCl, NaCl, KCl, RbCl, CsCl, MgCl₂, CaCl₂, SrCl₂, and BaCl₂, but the examples thereof are not limited thereto.

In the case where the metal oxide or metal salt layer is included, the thickness thereof is preferably 0.5 to 50 Å, and more preferably 1 to 20 Å. In the case where the thickness of the metal oxide or metal salt layer is very large, the driving voltage of the device may be increased.

In the exemplary embodiment of the present invention, a further organic material layer may be included between the third organic material layer comprising the n-type dopant and the light emitting layer, and the further organic material layer may be formed of an electron transport material.

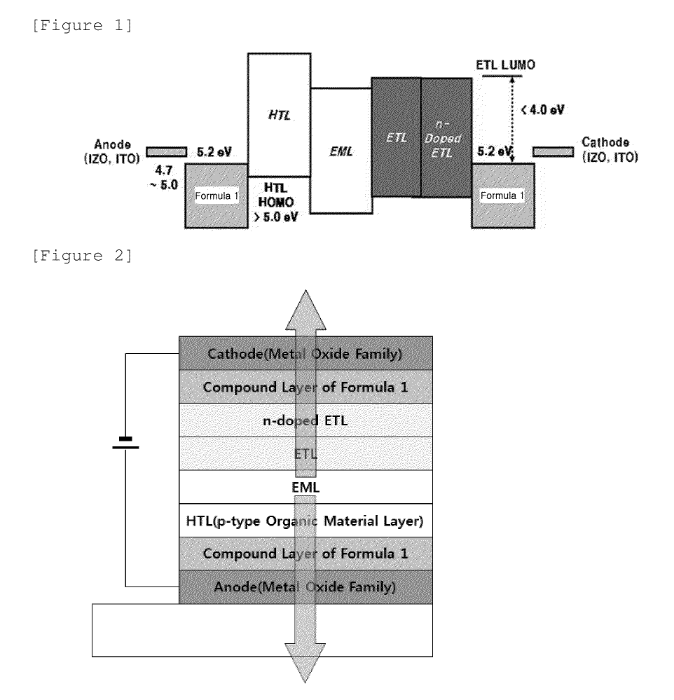

FIGS. 1 and 2 illustrate the organic light-emitting device according to an exemplary embodiment of the present invention. The organic light-emitting device shown in FIG. 2 has a structure where on a substrate, a transparent anode as a first electrode, an organic material layer comprising a compound of Formula 1 as a first organic material layer contacted with the first electrode, a p-type organic material layer as a hole transport layer (HTL), a light emitting layer (EML), an organic material layer comprising an n-type dopant, an organic material layer comprising the compound of Formula 1 as an organic material layer contacted with the second electrode, and a transparent cathode as the second electrode are sequentially layered. However, the scope of the present invention is not limited to this structure.

It is preferable that the organic light-emitting device according to the exemplary embodiment of the present invention has a normal structure where the first electrode is a lower electrode as an anode and the second electrode is an upper electrode as a cathode.

A method for manufacturing an organic light-emitting device according to the exemplary embodiment of the present invention comprises a step of forming a first electrode; a step of forming a first organic material layer contacted with the first electrode and comprising a compound of Formula 1; a step of forming a light emitting layer on the first organic material layer comprising the compound of Formula 1; a step of forming a third organic material layer comprising an n-type dopant on the light emitting layer; a step of forming a second organic material layer comprising the compound of Formula 1 on the third organic material layer comprising the n-type dopant; and a step of forming a second electrode so that the second electrode is contacted with the second organic material layer comprising the compound of Formula 1.

In addition, the method may further comprise a step of forming a p-type organic material layer that is contacted with the first organic material layer contacted with the first electrode between the first organic material layer contacted with the first electrode and the light emitting layer.

### MODE FOR INVENTION

Hereinafter, various exemplary embodiments and characteristics of the present invention will be described in more detail through Examples and Comparative Examples. However, the following Examples are set forth to illustrate various exemplary embodiments and characteristics of the present invention, but are not to be construed to limit the scope of the present invention.

### Example 1

The transparent anode (first electrode) having the thickness of 1000 Å was formed on the substrate by the sputtering method using IZO, the hole injection layer having the thickness of 500 Å was formed thereon by vacuum depositing HAT by heat, and the hole transport layer having the thickness of 400 Å was formed thereon by vacuum depositing NPB of the following Formula.

In addition, Ir(ppy)₃ of the following Formula was doped into CBP of the following Formula in the amount of 10 wt %, and the light emitting layer having the thickness of 300 Å was configured by the doped organic layer.

In addition, BAlq that was the hole blocking layer material of the following Formula was formed thereon in a thickness of 50 Å.

The electron transport material of the following Formula was formed thereon in a thickness of 150 Å, and the electron transport layer having the thickness of 50 Å doped by doping Ca to the electron transport material of the following Formula in the amount of 10 wt % was formed thereon.

When the second electrode was formed thereon, HAT having high crystallinity and the thickness of 500 Å was formed in order to prevent a damage due to sputtering (a difference between the LUMO level of the organic material layer including Ca and the LUMO level of the organic material layer including HAT contacted with the second electrode was 3.6 eV).

Finally, the cathode (second electrode) having the thickness of 1750 Å was formed by the sputtering method using IZO in order to manufacture the double-sided emission transparent device.

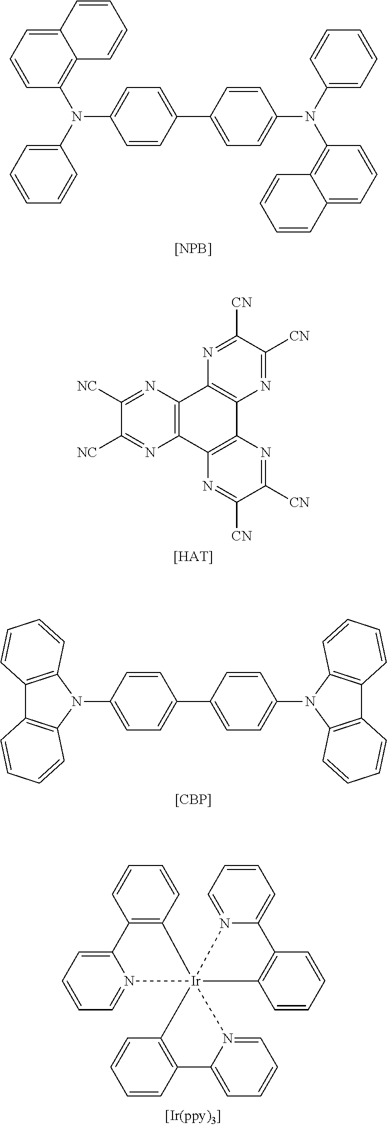

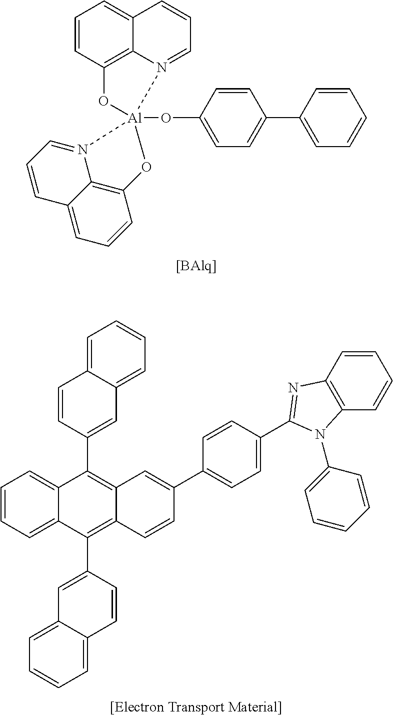

In the above process, the deposition speed of the organic material was maintained at 0.5 to 1.0 Å/sec, and the degree of vacuum during the deposition was maintained at about 2×10⁻⁷ to 2×10⁻⁸ torr.

The results of each voltage, brightness and spectrum were measured by sequentially applying the voltage at the interval of 0.2 mA/cm² to the organic light-emitting device manufactured in Example 1 (device 2).

### Comparative Example 1

The transparent anode (first electrode) having the thickness of 1000 Å was formed on the substrate by the sputtering method using IZO, the hole injection layer having the thickness of 500 Å was formed thereon by vacuum depositing HAT by heat, and the hole transport layer having the thickness of 400 Å was formed thereon by vacuum depositing NPB of the above Formula.

In addition, Ir(ppy)₃ of the above Formula was doped into CBP of the above Formula in the amount of 10 wt %, the light emitting layer having the thickness of 300 Å was configured by the doped organic layer, and BAlq that was the hole blocking layer material of the above Formula was formed thereon in a thickness of 50 Å.

The electron transport material used in Example 1 was formed thereon in a thickness of 200 Å, and HAT was formed in the thickness of 500 Å while the n-doped organic material layer was not configured. Finally, the cathode (second electrode) having the thickness of 1750 Å was formed by the sputtering method using IZO in order to manufacture the double-sided emission transparent device.

In the above process, the deposition speed of the organic material was maintained at 0.5 to 1.0 Å/sec, and the degree of vacuum during the deposition was maintained at about 2×10⁻⁷ to 2×10⁻⁸ torr.

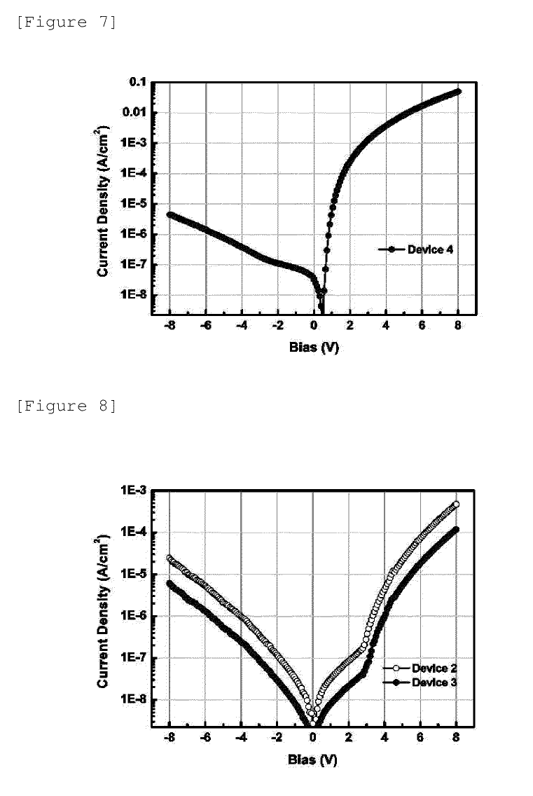

As a result of the present Comparative Example, the driving of the device was not implemented in the device where the n-doped organic material layer was not configured. The experiment results are shown in the following Table 1 and the current density-voltage graph of FIG. 7 (device 4). In the result shown in FIG. 7, the electron was not transported from the HAT layer to the electron transport layer, and only the hole was transported from the electron transport layer to the HAT layer, such that in the device, only the hole was transported without efficient injection of the electron. In this device, since recombination between the electron and the hole in the light emitting layer was not implemented, light emission of the device was not observed.

### Comparative Example 2

The transparent anode (first electrode) having the thickness of 1000 Å was formed on the substrate by the sputtering method using IZO, the hole injection layer having the thickness of 500 Å was formed thereon by vacuum depositing HAT by heat, and the hole transport layer having the thickness of 400 Å was formed thereon by vacuum depositing NPB of the above Formula.

In addition, Ir(ppy)₃ of the above Formula was doped into CBP of the above Formula in the amount of 10 wt %, the light emitting layer having the thickness of 300 Å was configured by the doped organic layer, and BAlq that was the hole blocking layer material of the above Formula was formed thereon in a thickness of 50 Å.

The electron transport material used in Example 1 was formed thereon in the thickness of 150 Å, and Ca was doped by 10% in the thickness of 50 Å into the electron transport material. However, the HAT layer was not formed thereon. Finally, the cathode (second electrode) having the thickness of 1750 Å was formed by the sputtering method using IZO in order to manufacture the double-sided emission transparent device.

In the above process, the deposition speed of the organic material was maintained at 0.5 to 1.0 Å/sec, and the degree of vacuum during the deposition was maintained at about 2×10⁻⁷ to 2×10⁻⁸ torr (device 1).

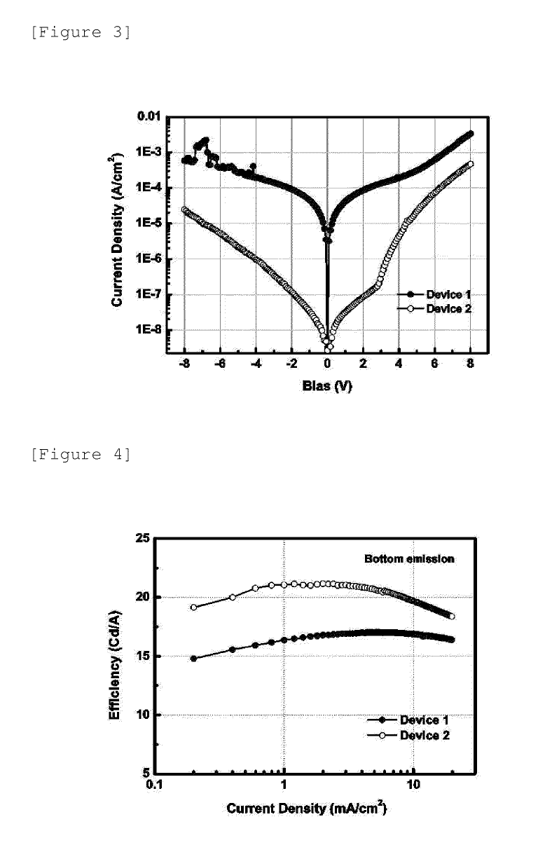

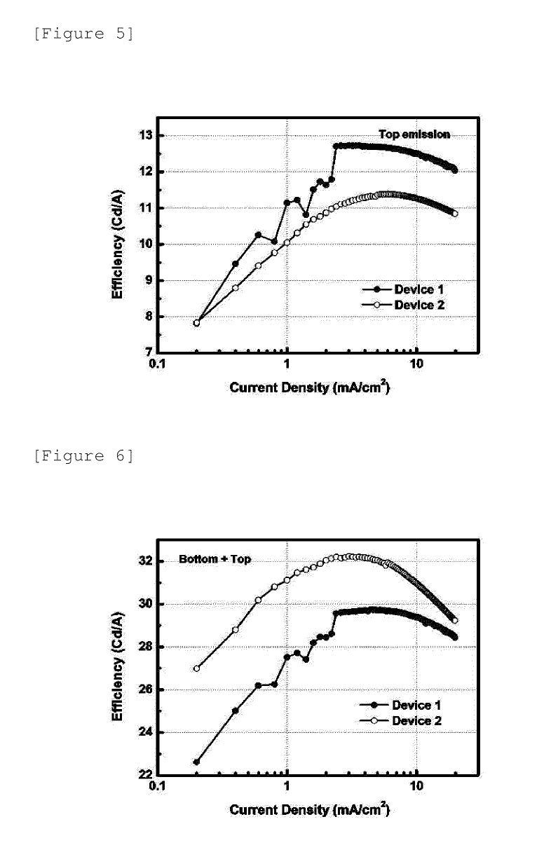

The result of the present Comparative Example 2 was compared to the result of Example, and shown in the following Table 1 and FIGS. 3, 4, 5, and 6.

As shown in FIG. 3, in the case where the HAT layer was not configured like the present Comparative Example 2 (device 1), it can be seen that the degree of leakage current is largely high as compared to the case where the HAT was configured like Example (device 2). This is an example showing that there is a damage of the device when the HAT layer is not used in the sputtering process.

### Comparative Example 3

The transparent anode (first electrode) having the thickness of 1000 Å was formed on the substrate by the sputtering method using IZO, HAT was not configured thereon, and the hole transport layer having the thickness of 900 Å was directly formed thereon by vacuum depositing NPB of the above Formula.

In addition, Ir(ppy)₃ of the above Formula was doped into CBP of the above Formula in the amount of 10 wt %, the light emitting layer having the thickness of 300 Å was configured by the doped organic layer, and BAlq that was the hole blocking layer material of the above Formula was formed thereon in a thickness of 50 Å.

The electron transport material used in Example 1 was formed in the thickness of 150 Å, and Ca was doped by 10% in the thickness of 50 Å into the electron transport material. However, the HAT layer was not formed thereon. Finally, the cathode (second electrode) having the thickness of 1750 Å was formed by the sputtering method using IZO in order to manufacture the double-sided emission transparent device.

In the above process, the deposition speed of the organic material was maintained at 0.5 to 1.0 Å/sec, and the degree of vacuum during the deposition was maintained at about 2×10⁻⁷ to 2×10⁻⁸ torr.

The result of the present Comparative Example is briefly shown in the following Table 1. Table 1 shows characteristics of the device at the current density of 1 mA/cm². As shown in the result of Table 1, when HAT is not configured in the anode (first electrode), the driving voltage of the device is increased, and efficiency is reduced.

### Example 2

The transparent anode (first electrode) having the thickness of 1000 Å was formed on the substrate by the sputtering method using IZO, the hole injection layer having the thickness of 500 Å was formed thereon by vacuum depositing HAT by heat, and the hole transport layer having the thickness of 400 Å was formed thereon by vacuum depositing NPB of the above Formula.

In addition, Ir(ppy)₃ of the above Formula was doped into CBP of the above Formula in the amount of 10 wt % to configure the light emitting layer having the thickness of 300 Å, and BAlq that was the hole blocking layer material was formed thereon in a thickness of 50 Å.

The electron transport material used in Example 1 was formed thereon in a thickness of 150 Å, and the electron transport layer having the thickness of 50 Å doped by doping Ca to the electron transport material used in Example 1 in the amount of 10 wt % was formed thereon. LiF that was the metal salt was deposited in the thickness of 15 Å thereon, and HAT having the high crystallinity was formed in the thickness of 500 Å in order to prevent a damage due to sputtering when the second electrode was formed thereon.

Finally, the cathode (second electrode) having the thickness of 1750 Å was formed by the sputtering method using IZO in order to manufacture the double-sided emission transparent device.

In the above process, the deposition speed of the organic material was maintained at 0.5 to 1.0 Å/sec, and the degree of vacuum during the deposition was maintained at about 2×10⁻⁷ to 2×10⁻⁸ torr.

The results of each voltage, brightness and spectrum were measured by sequentially applying the voltage at the interval of 0.2 mA/cm² to the organic light-emitting device manufactured in Example 2 (device 3).

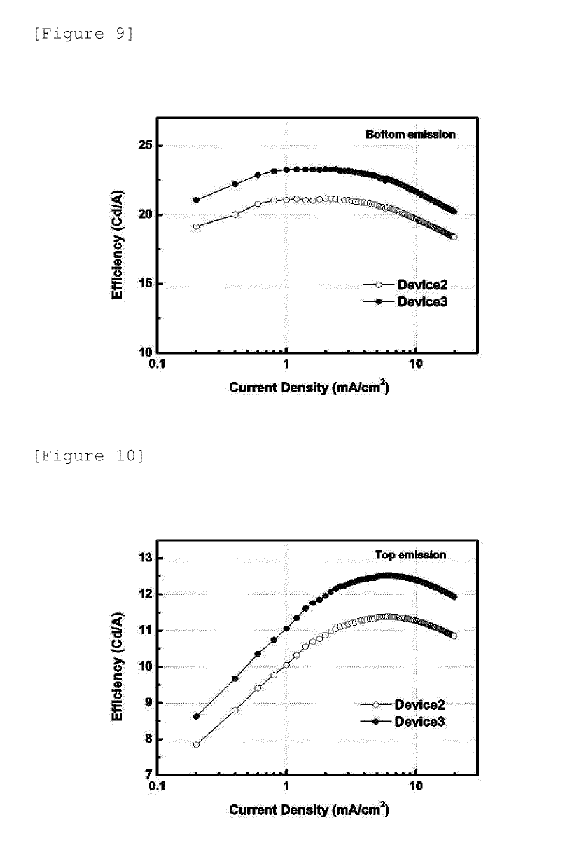

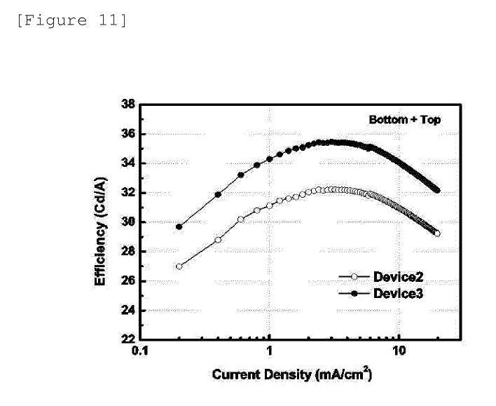

The result of Example 2 was compared to that of Example 1, and shown in the following Table 1 and FIGS. 8, 9, 10, and 11. The voltage was apt to be increased as compared to Example 1, but as shown in FIGS. 9, 10, and 11, it can be seen that efficiency can be improved by effective blocking of the hole.

### Example 3

The transparent anode (first electrode) having the thickness of 1000 Å was formed on the substrate by the sputtering method using IZO, and Ag was deposited thereon in the thickness of 200 Å. The hole injection layer having the thickness of 500 Å was formed on deposited Ag by vacuum depositing HAT by heat, and the hole transport layer having the thickness of 400 Å was formed thereon by vacuum depositing NPB of the above Formula.

In addition, Ir(ppy)₃ of the above Formula was doped into CBP of the above Formula in the amount of 10 wt % to configure the light emitting layer having the thickness of 300 Å, and BAlq that was the hole blocking layer material was formed thereon in a thickness of 50 Å.

The electron transport material used in Example 1 was formed thereon in a thickness of 150 Å, and the electron transport layer having the thickness of 50 Å doped by doping Ca to the electron transport material used in Example 1 in the amount of 10 wt % was formed thereon. LiF that was the metal salt was deposited in the thickness of 15 Å thereon, and HAT having the high crystallinity was formed in the thickness of 500 Å in order to prevent a damage due to sputtering when the second electrode was formed thereon.

Finally, the cathode (second electrode) having the thickness of 1750 Å was formed by the sputtering method using IZO in order to manufacture the double-sided emission transparent device.

In the above process, the deposition speed of the organic material was maintained at 0.5 to 1.0 Å/sec, and the degree of vacuum during the deposition was maintained at about 2×10⁻⁷ to 2×10⁻⁸ torr.

The present Example 3 is the experiment where the metal thin film was formed between the HAT layer contacted with the anode (first electrode) and the anode, and the results are briefly compared and shown in the following Table 1. As shown in Table 1, if the device is manufactured by adding the metal thin film layer, efficiency may be slightly reduced due to a reduction of transmittance of the metal thin film layer, but there is an advantage in that the driving voltage of the device is reduced.

TABLE 1

| | | Current | |
|---|---|---|---|
| | | efficiency | Current |
| | | (cd/A) | efficiency |
| | Driving | (Bottom | (cd/A) (Top |
| @1 mA/cm² | voltage (V) | direction) | direction) |
| Example 1 | 9 | 21 | 10 |
| (Device 2) | | | |
| Comparative | — | — | — |
| Example 1 | | | |
| (Device 4) | | | |
| Comparative | 7 | 21 | — |
| Example 2 | | | |
| (Device 1) | | | |
| Comparative | 15 | 16 | 8 |
| Example 3 | | | |
| (Device 5) | | | |
| Example 2 | 12 | 23 | 11 |
| (Device 3) | | | |
| Example 3 | 8 | 11 | 12 |
| (Device 6) | | | |

1. An organic light-emitting device, comprising:
a first electrode;
a second electrode; and
a light emitting layer that is disposed between the first electrode and the second electrode,
wherein the organic light-emitting device further comprises a first organic material layer that is contacted with the first electrode and a second organic material layer that is contacted with the second electrode, the first and the second organic material layers comprise a compound represented by the following Formula 1, and a third organic material layer comprising an n-type dopant between the second organic material layer contacted with the second electrode and the light emitting layer is included: 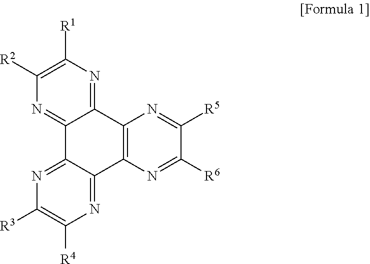
wherein R¹ to R⁶ are each selected from the group consisting of hydrogen, a halogen atom, nitrile (—CN), nitro (—NO₂), sulfonyl (—SO₂R), sulfoxide (—SOR), sulfonamide (—SO₂NR), sulfonate (—SO₃R), trifluoromethyl (—CF₃), ester (—COOR), amide (—CONHR or —CONRR′), substituted or unsubstituted straight-chained or branched-chained C₁-C₁₂ alkoxy, substituted or unsubstituted straight-chained or branched-chained C₁-C₁₂ alkyl, substituted or unsubstituted aromatic or non-aromatic hetero cycle, substituted or unsubstituted aryl, substituted or unsubstituted mono- or di-arylamine, and substituted or unsubstituted aralkylamine, and R and R′ are each selected from the group consisting of substituted or unsubstituted C₁-C₆₀ alkyl, substituted or unsubstituted aryl and substituted or unsubstituted 5 to 7-membered hetero cycle.

2. The organic light-emitting device according to claim 1, wherein the first and the second organic material layers are the same material as each other.

3. The organic light-emitting device according to claim 1, wherein the n-type dopant of the third organic material layer comprising the n-type dopant comprises the material comprising one selected from the group consisting of alkali metal, alkali earth metal, rare earth metal, metal compound, cyclopentadiene, cycloheptatriene, 6-membered heterocycle and compensation cycle including the cycles.

4. The organic light-emitting device according to claim 1, wherein the content of the n-type dopant of the third organic material layer comprising the n-type dopant is 1 to 50 wt %.

5. The organic light-emitting device according to claim 1, wherein the third organic material layer comprising the n-type dopant comprises a compound having a functional group selected from the group consisting of an imidazole group, an oxazole group and a thiazole group.

6. The organic light-emitting device according to claim 1, wherein the LUMO (Lowest unoccupied molecular orbital) level of the third organic material layer comprising the n-type dopant has an energy difference of 4 eV or less in respects to the LUMO level of the second organic material layer contacted with the second electrode.

7. The organic light-emitting device according to claim 1, further comprising:
a p-type organic material layer contacted with the first organic material layer between the first organic material layer and the light emitting layer.

8. The organic light-emitting device according to claim 7, wherein the HOMO (highest occupied molecular orbital) level of the p-type organic material layer is 5 eV or more.

9. The organic light-emitting device according to claim 1, wherein the first electrode and the second electrode each comprises a material having a work function of 2 eV to 6 eV.

10. The organic light-emitting device according to claim 1, wherein the first electrode and the second electrode are formed of the same metal oxide or different metal oxides.

11. The organic light-emitting device according to claim 1, wherein the first electrode and the second electrode are formed of the same material.

12. The organic light-emitting device according to claim 1, wherein at least one of the first electrode and the second electrode comprises a transparent material.

13. The organic light-emitting device according to claim 1, wherein the organic light-emitting device has a normal structure where the first electrode is a lower electrode as an anode and the second electrode is an upper electrode as a cathode.

14. The organic light-emitting device according to claim 1, further comprising:
a thin film of metal or an alloy thereof, or a metal oxide layer at an interface between the first electrode and the first organic material layer contacted with the first electrode.

15. The organic light-emitting device according to claim 1, further comprising:
a metal oxide layer or a metal salt layer at an interface between the second organic material layer contacted with the second electrode and the third organic material layer comprising the n-type dopant.

16. A method for manufacturing the organic light-emitting device according to claim 1, comprising:
a step of forming a first electrode;
a step of forming a first organic material layer contacted with the first electrode and comprising a compound of the following Formula 1;
a step of forming a light emitting layer on the first organic material layer;
a step of forming a third organic material layer comprising an n-type dopant on the light emitting layer;
a step of forming a second organic material layer comprising a compound of the following Formula 1 on the third organic material layer; and
a step of forming a second electrode so that the second electrode is contacted with the second organic material layer: 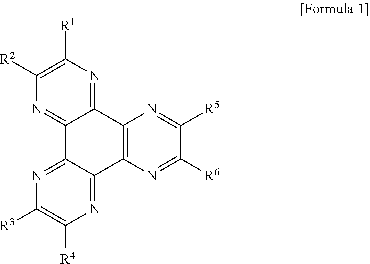
wherein R¹ to R⁶ are each selected from the group consisting of hydrogen, a halogen atom, nitrile (—CN), nitro (—NO₂), sulfonyl (—SO₂R), sulfoxide (—SOR), sulfonamide (—SO₂NR), sulfonate (—SO₃R), trifluoromethyl (—CF₃), ester (—COOR), amide (—CONHR or —CONRR′), substituted or unsubstituted straight-chained or branched-chained C₁-C₁₂ alkoxy, substituted or unsubstituted straight-chained or branched-chained C₁-C₁₂ alkyl, substituted or unsubstituted aromatic or non-aromatic hetero cycle, substituted or unsubstituted aryl, substituted or unsubstituted mono- or di-arylamine, and substituted or unsubstituted aralkylamine, and R and R′ are each selected from the group consisting of substituted or unsubstituted C₁-C₆₀ alkyl, substituted or unsubstituted aryl and substituted or unsubstituted 5 to 7-membered hetero cycle.

17. The method for manufacturing the organic light-emitting device according to claim 16, further comprising:
a step of forming a p-type organic material layer that is contacted with the first organic material layer, between the first organic material layer and the light emitting layer.

18. The method for manufacturing the organic light-emitting device according to claim 16, further comprising:
a step of forming a thin film of metal or an alloy thereof, or a metal oxide layer at an interface between the first electrode and the first organic material layer contacted with the first electrode.

19. The method for manufacturing the organic light-emitting device according to claim 16, further comprising:
a step of forming a metal oxide layer or a metal salt layer at an interface between the second organic material layer contacted with the second electrode and the third organic material layer comprising the n-type dopant.
